(19) United States
(12) Patent Application Publication
(10) Pub. No.: US 2025/0007245 A1
(43) Pub. Date: Jan. 2, 2025

(54) MODE FILTER FOR A BACKSIDE EMITTING VERTICAL-CAVITY SURFACE-EMITTING LASER

(71) Applicant: Lumentum Operations LLC, San Jose, CA (US)

(72) Inventors: Richa DUBEY, Milpitas, CA (US); Eric R. HEGBLOM, Sunnyvale, CA (US); Benjamin KESLER, Livemore, CA (US); Matthew Glenn PETERS, Menlo Park, CA (US)

(21) Appl. No.: 18/545,901

(22) Filed: Dec. 19, 2023

Related U.S. Application Data
(60) Provisional application No. 63/511,480, filed on Jun. 30, 2023.

(51) Int. Cl. H01S 5/183

(52) U.S. Cl. CPC H01S 5/18377; H01S 5/18311; H01S 5/18355; H01S 2301/166

(57) ABSTRACT

A vertical-cavity surface-emitting laser (VCSEL) may include a first mirror structure over a cavity region. The VCSEL may include a grating associated with polarizing light emitted by the VCSEL. The grating may be over the first mirror structure. The VCSEL may include a mode filter (MF) structure over the grating. The MF structure may comprise an MF layer in a first region of the MF structure to at least partially suppress a higher order transverse mode (HOM) of the light, the MF layer comprising a dielectric layer. The MF structure may include a second minor structure in at least a second region of the MF structure to increase reflectivity on a side of the VCSEL comprising the first minor structure.

### CROSS-REFERENCE TO RELATED APPLICATION

This Patent Application claims priority to U.S. Provisional Patent Application No. 63/511,480, filed on Jun. 30, 2023, and entitled “MODE SELECTION FOR A SINGLE MODE BACKSIDE EMITTING POLARIZED VERTICAL-CAVITY SURFACE-EMITTING LASER.” The disclosure of the prior Application is considered part of and is incorporated by reference into this Patent Application.

### TECHNICAL FIELD

The present disclosure relates generally to a vertical-cavity surface-emitting laser (VCSEL) and to mode selection for a mode filter for a backside emitting (BSE) VCSEL.

### BACKGROUND

A VCSEL is a semiconductor laser, more specifically a diode laser with a monolithic laser resonator, where light is emitted in a direction perpendicular to a chip surface. Typically, the laser resonator consists of two distributed Bragg reflector (DBR) mirrors parallel to a chip surface, between which is a cavity region (consisting of one or more quantum wells) that generates light. Commonly, the upper and lower minors of a VCSEL are doped as p-type and n-type materials, respectively, thereby forming a diode junction.

### SUMMARY

In some implementations, a VCSEL includes a first minor structure over a cavity region; a grating associated with polarizing light emitted by the VCSEL, the grating being over the first minor structure; and a mode filter (MF) structure over the grating, the MF structure comprising: an MF layer in a first region of the MF structure to at least partially suppress a higher order transverse mode (HOM) of the light, the MF layer comprising a dielectric layer, and a second mirror structure in at least a second region of the MF structure to increase reflectivity on a side of the VCSEL comprising the first mirror structure.

In some implementations, a backside emitting (BSE) VCSEL includes a first minor structure over a cavity region; and an MF structure over the first minor structure, the MF structure comprising: an MF layer in a first region, the MF layer being associated with suppressing one or more modes of light emitted by the BSE VCSEL, wherein the MF layer comprises at least a dielectric layer, and a second minor structure in at least a second region, the second minor structure being associated with increasing reflectivity on a side of the BSE VCSEL that includes the first minor structure.

In some implementations, a VCSEL includes an MF structure comprising: an MF layer to provide an offset between a first region of the MF structure and a second region of the MF structure in association with at least partially suppressing one or more modes of light emitted by the VCSEL by causing destructive interference in reflectivity in the first region of the MF structure; and a minor structure in at least the second region to increase reflectivity on an epitaxial side of the VCSEL.

### BRIEF DESCRIPTION OF THE DRAWINGS

FIG. 1 is a diagram associated with an example implementation of a VCSEL including an MF structure as described herein.

FIG. 2 is a diagram associated with an alternative example implementation of a VCSEL including an MF structure as described herein.

FIGS. 3 and 4 are diagrams illustrating simulation results of a VCSEL including the MF structure described herein.

### DETAILED DESCRIPTION

The following detailed description of example implementations refers to the accompanying drawings. The same reference numbers in different drawings may identify the same or similar elements.

A VCSEL that achieves single mode operation emits a beam of light with a Gaussian-type profile with high reliability while requiring low input power, meaning that single mode operation of a VCSEL is desirable in many applications. A conventional technique to achieve single mode operation for a BSE VCSEL is to reduce a size of an oxide aperture of the VCSEL. However, reducing the size of the oxide aperture reduces output power of the VCSEL and decreases manufacturability of the VCSEL.

Some implementations described herein include a mode filter (MF) for a VCSEL, such as a BSE VCSEL. In some implementations, the VCSEL includes a first minor structure over a cavity region and an MF structure over the first mirror structure. The MF structure may include an MF layer in a first region of the MF structure and a second minor structure in at least a second region of the MF structure. In some implementations, the MF layer comprises a dielectric layer and at least partially suppresses one or more modes of light (e.g., one or more higher order transverse modes of light) emitted by the VCSEL. In some implementations, the second minor structure increases reflectivity on a side of the VCSEL comprising the first mirror structure. In some implementations, the VCSEL may further include a grating associated with polarizing the light.

In some implementations, the VCSEL described herein provides controllability of operation of the VCSEL. For example, the VCSEL described herein may be designed so as to achieve low divergence or single mode operation (e.g., at high bias currents). Further, the VCSEL described herein may have improved performance uniformity (e.g., as compared to a BSE VCSEL that includes a relatively smaller oxide aperture in association with achieving single mode operation). Additional details are provided below.

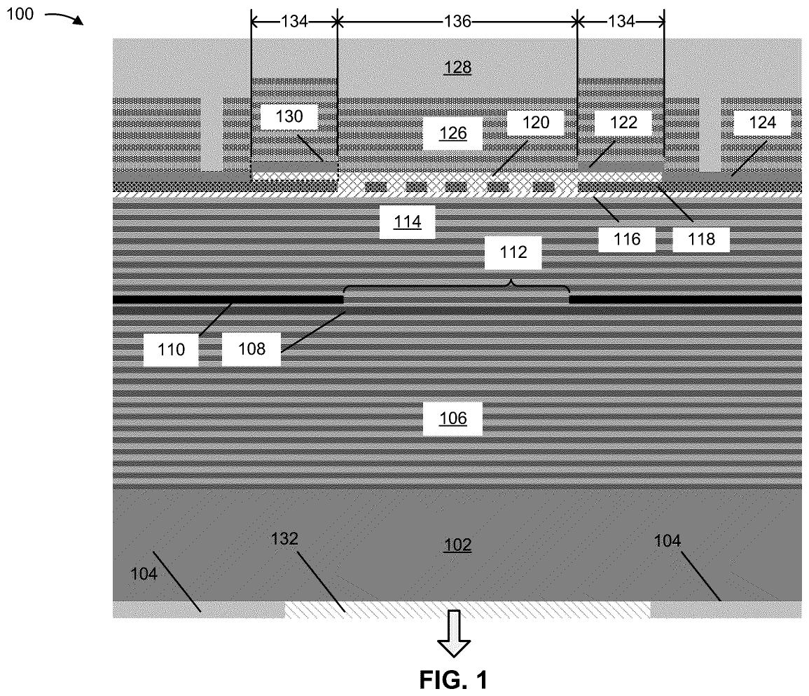

FIG. 1 is a diagram associated with an example implementation of a VCSEL 100 including an MF structure as described herein. In some implementations, the VCSEL 100 may be included in an array of emitters (e.g., an array of VCSELs 100). In some implementations, as illustrated in FIG. 1, the VCSEL 100 is a BSE VCSEL, meaning that the VCSEL 100 emits light through the substrate 102 of the VCSEL 100.

As shown in FIG. 1, the VCSEL 100 may include a substrate 102, a bottom metal 104, a bottom mirror structure 106, a cavity including one or more active regions (herein referred to as cavity region(s) 108), a confinement layer 110 that forms a confinement aperture 112, a first top mirror structure 114, an etch stop layer 116, a cap layer 118, a dielectric layer 120, a metal layer 122, a top contact layer 124, a second top mirror structure 126, and a top metal 128. In some implementations, the MF structure of the VCSEL 100 comprises the second top mirror structure 126 and an MF layer 130 formed from a portion of the dielectric layer 120 and the (optional) metal layer 122. Additional details regarding the MF structure are provided below.

Substrate 102 includes a supporting material upon which, or within which, one or more layers or features of the VCSEL 100 are grown or fabricated. In some implementations, the substrate 102 comprises an n-type material. In some implementations, the substrate 102 comprises a semi-insulating type of material. In some implementations, when the VCSEL 100 includes one or more bottom-emitting emitters, the semi-insulating type of material may be used to reduce optical absorption from the substrate 102. In such an implementation, the VCSEL 100 may include a contact buffer in or near the bottom mirror structure 106. In some implementations, the substrate 102 may include a semiconductor material, such as gallium arsenide (GaAs), indium phosphide (InP), or another type of semiconductor material. In some implementations, a bottom contact (e.g., a bottom n-contact) of the VCSEL 100 can be made from a backside of the substrate 102. In some implementations, the bottom contact of the VCSEL 100 can be made from a front side of the VCSEL 100. In some implementations, the front side contact can be achieved by, for example, etching a mesa step or trench to the substrate 102, or inserting a contact buffer in or near the bottom mirror structure 106.

Bottom metal 104 includes a metal layer on a bottom surface of the substrate 102 (e.g., at a backside of the VCSEL 100). In some implementations, the bottom metal 104 is formed from an n-type material. In some implementations, the bottom metal 104 is a layer that makes electrical contact with the substrate 102. In some implementations, the bottom metal 104 serves as an anode for the VCSEL 100. In some implementations, the bottom metal 104 may include an annealed metallization layer, such as a gold-germanium-nickel (AuGeNi) layer, or a palladium-germanium-gold (PdGeAu) layer, among other examples. In some implementations, as shown in FIG. 1, an anti-reflective (AR) coating 132 may be formed in an opening in the bottom metal 104 (e.g., an opening through which the VCSEL 100 is to emit light).

Bottom mirror structure 106 is a bottom reflector of an optical resonator of the VCSEL 100. For example, the bottom mirror structure 106 may include a plurality of distributed Bragg reflector (DBR) pairs, or another type of minor structure. In some implementations, the bottom mirror structure 106 is formed from an n-type material. Thus, in some implementations, the bottom mirror structure 106 may include a plurality of n-type DBR pairs. Alternatively, the bottom mirror structure 106 may in some implementations be formed from a p-type material. In some implementations, the bottom mirror structure 106 is on a (top) surface of the substrate 102. In some implementations, the bottom mirror structure 106 may have a thickness in a range from approximately 3.5 micrometers (μm) to approximately 9 μm, such as 5 μm. In some implementations, the bottom minor structure 106 includes a set of layers (e.g., aluminum gallium arsenide (AlGaAs) layers) grown using a metal-organic chemical vapor deposition (MOCVD) technique, a molecular beam epitaxy (MBE) technique, or another technique.

Cavity region 108 includes one or more layers where electrons and holes recombine to emit light and define the emission wavelength range of the VCSEL 100. For example, the cavity region 108 may include one or more active regions in the form of one or more quantum wells (QWs). In some implementations, the cavity region 108 may include one or more cavity spacer layers (e.g., to enable epitaxial growth to have sufficient room for ramping compositions or temperature). In some implementations, the one or more cavity spacer layers may reduce strain between active regions of the cavity region 108 and/or may mitigate thermal issues of laser operation of the VCSEL 100. In some implementations, the one or more cavity spacer layers may include an oxidation layer. An optical thickness of the cavity region 108 (including the one or more active regions and any cavity spacer layers), the first top mirror structure 114, the second top minor structure 126, and the bottom minor structure 106 may define a resonant cavity wavelength of the VCSEL 100, which may be designed within an emission wavelength range of the cavity region 108 to enable lasing. The wavelength range of the VCSEL 100 may in some implementations be in a range from approximately 940 nanometers (nm) to approximately 1380 nm. In some implementations, the cavity region 108 may be formed on the bottom mirror structure 106. In some implementations, the cavity region 108 may have a thickness in a range from approximately 0.006 μm to approximately 0.5 μm, such as 0.15 μm or 0.30 μm. In some implementations, the cavity region 108 includes a set of layers grown using an MOCVD technique, an MBE technique, or another technique.

Confinement layer 110 is a layer that provides optical and/or electrical confinement for the VCSEL 100. In some implementations, the confinement layer 110 enhances carrier and mode confinement of the VCSEL 100 and, therefore, can improve performance of the VCSEL 100. In some implementations, the confinement layer 110 is on, under, or in the cavity region 108. In some implementations, there may be one or more spacer layers or mirror layers (e.g., DBRs) between the confinement layer 110 and the cavity region 108. In some implementations, as shown in FIG. 1, the confinement layer 110 is on a side of the cavity region 108 nearer to the first top mirror structure 114 (i.e., on a non-substrate side of the cavity region 108). In some implementations, the confinement layer 110 is on a side of the cavity region 108 nearer to the bottom mirror structure 106 (i.e., on a substrate side of the cavity region 108).

In some implementations, the confinement layer 110 comprises an oxide layer formed by oxidation of one or more epitaxial layers of the VCSEL 100. For example, the confinement layer 110 may be an aluminum oxide (Al₂O₃) layer formed as a result of oxidation of an epitaxial layer (e.g., an AlGaAs layer, an AlAs layer, and/or the like). In some implementations, the confinement layer 110 may have a thickness in a range from approximately 0.007 μm to approximately 0.04 μm, such as 0.02 μm. In some implementations, oxidation trenches etched around the VCSEL 100 may allow steam to access the epitaxial layer(s) from which the confinement layer 110 is formed. In some implementations, the oxidation trenches may not fully enclose the confinement layer 110. For example, the oxidation trenches may follow the general shape of the confinement region, but there may be gaps between adjacent oxidation trenches. In some implementations, the confinement layer 110 may follow the general geometric shape, but may have variations associated with shapes or locations of the oxidation trenches and/or variations associated with an oxidation rate. In some implementations, in addition to the confinement layer 110, the VCSEL 100 may include one or more other types of structures or layers that provide current confinement, such as an implant passivation structure, a mesa isolation structure, a moat trench isolation structure, a buried tunnel junction, or the like. Additionally, or alternatively, other types of structures or layers for providing current confinement may be included in or integrated with the confinement layer 110.

In some implementations, the confinement layer 110 defines the confinement aperture 112. Thus, in some implementations, the confinement aperture 112 is an optically active aperture defined by the confinement layer 110. In some implementations, a size (e.g., a width in a given direction) of the confinement aperture 112 is in a range from approximately 1 μm to approximately 300 μm, such as 5 μm or 8 μm. In some implementations, as described above, the confinement aperture 112 may be formed by oxidation (e.g., when the confinement layer 110 is an oxidized layer). Additionally, or alternatively, the confinement aperture 112 may be formed by other means, such as by implantation, diffusion, regrowth (e.g., using a high resistance layer, a current blocking layer, a tunnel junction, or the like), or an air gap, among other examples.

First top minor structure 114 is a top reflector of the optical resonator of the VCSEL 100. For example, the first top mirror structure 114 may include a plurality of DBR pairs, or another type of mirror structure. In some implementations, the first top mirror structure 114 is formed from a p-type material. Thus, in some implementations, the first top minor structure 114 comprises a plurality of p-type DBR pairs. Alternatively, the first top mirror structure 114 may in some implementations be formed from an n-type material. In some implementations, the first top minor structure 114 may have a thickness in a range from approximately 1 μm to approximately 4 μm, such as 2 μm. In some implementations, a quantity of minor pairs in the first top mirror structure 114 is in a range from seven mirror pairs to seventeen mirror pairs. In some implementations, the quantity of mirror pairs in the first top minor structure 114 may be based on a quantity of mirror pairs in the second top mirror structure 126. In some implementations, the first top minor structure 114 includes a set of layers (e.g., AlGaAs layers) grown using an MOCVD technique, an MBE technique, or another technique. In some implementations, the first top minor structure 114 is grown on or over the cavity region 108.

Etch stop layer 116 is a layer used to prevent etching of one or more other layers during an etching process. In the VCSEL 100, the etch stop layer can be used during etching of the cap layer 118 (e.g., during formation of a polarization grating) to prevent etching of the first top mirror structure 114. In some implementations, the etch stop layer 116 may comprise, for example, indium gallium phosphide (InGaP), or another type of material. In some implementations, the etch stop layer 116 is optional (i.e., the etch stop layer 116 may not be present in some implementations of the VCSEL 100).

Cap layer 118 is a layer associated with capping or protecting one or more layers or features of the VCSEL. Additionally, the cap layer 118 may in some implementations comprise a grating associated with polarizing light emitted by the VCSEL 100. In some implementations, the grating introduces a polarization dependence to reflectivity of the VCSEL 100, an effect of which is suppression of one of the two orthogonal polarization orientations in the light (e.g., such that the light emitted by the VCSEL 100 has a single polarization orientation). In some implementations, as shown in FIG. 1, the cap layer 118 is over the first top mirror structure 114. In some implementations, the cap layer 118 comprises a semiconductor material, such as GaAs, that is etched to form a grating pattern that defines the grating. The grating pattern may comprise, for example, a series of lines (e.g., from a top view of the VCSEL 100). In some implementations, a pitch of the grating pattern may be in a range from approximately 0.35 μm to approximately 0.66 μm. Additionally, or alternatively, the pitch of the grating pattern may be in a range from approximately 0.35×λ to approximately 0.48×λ, where λ is a wavelength of the VCSEL 100. Notably, with proper design of the top mirror structure 114 and the second top mirror structure 126, serving as a back-reflector, the grating pitch may be larger than the optical wavelength in the semiconductor without causing significant degradation of device performance (e.g., optical power, polarization, mode selectivity, or the like), and the larger pitch may ease fabrication as compared to alternative designs that require sub-wavelength gratings. In some implementations, a duty cycle (e.g., ratio of a grating ridge width to a period) of the grating pattern may be in a range from approximately 0.40 to approximately 0.60. In some implementations, a depth of the grating pattern may be in a range from approximately 100 nanometers (nm) to approximately 150 nm. In some implementations, the grating is optional (i.e., the grating may not be present in some implementations of the VCSEL 100). In such an implementation, the VCSEL 100 may, for example, provide unpolarized light (e.g., single mode light or multi-mode light) with controlled (e.g., low) divergence provided by the MF structure as described herein.

Dielectric layer 120 is a layer to create an out-of-phase region for higher order transverse modes (HOMs) of light in the VCSEL 100 in association with providing mode filtering for the VCSEL 100. In some implementations, a portion of the dielectric layer 120 may be included in the MF layer 130. In some implementations, the dielectric layer 120 may comprise, for example, SiNx, SiO₂, a polymer dielectric, or another type of insulating material. In some implementations, a thickness of the dielectric layer 120 is selected so as to cause destructive interference in reflectivity in a first region 134 of the MF structure. Additional details regarding the dielectric layer 120 are provided below in the description related to the MF layer 130.

Metal layer 122 is a layer to provide lateral absorption of HOMs in the VCSEL 100 in association with providing mode filtering for the VCSEL 100. Additionally, or alternatively, the metal layer 122 may be formed to create (in combination with the dielectric layer 120) the out-of-phase region for HOMs of light in the VCSEL 100. In some implementations, the metal layer 122 may be included in the MF layer 130. In some implementations, the metal layer 122 may comprise the same material as the top contact layer 124. For example, in some implementations, the metal layer 122 may be formed from the same p-type metal from which the top contact layer 124 is formed. In some implementations, using the same material for both the metal layer 122 and the top contact layer 124 reduces manufacturing complexity of the VCSEL 100 (e.g., by enabling the metal layer 122 and the top contact layer 124 to be formed using the same deposition process). Additionally, or alternatively, the metal layer 122 may comprise the same material as a plating metal (e.g., a gold (Au)) of the VCSEL 100. Additionally, or alternatively, the metal layer 122 may comprise the same material as a seed metal (e.g., titanium tungsten (TiW)/Au) of the VCSEL 100. In some implementations, the metal layer 122 has a thickness in a range from approximately 0.2 μm to approximately 0.8 μm, such as 0.5 μm. In some implementations, the metal layer 122 has a ring shape, a slotted ring shape, a tooth wheel shape, or another type of circular or non-circular shape (e.g., depending on a design of the VCSEL 100). In some implementations, a shape of the metal layer 122 corresponds to or matches a shape of the confinement aperture 112. In some implementations, the metal layer 122 is optional and therefore may not be present in some implementations of the VCSEL 100. Additional details regarding the metal layer 122 are provided below in the description related to the MF layer 130.

Top contact layer 124 is a top contact layer of the VCSEL 100 that makes electrical contact with the first top minor structure 114 through which current may flow. In some implementations, the top contact layer 124 is formed from materials optimized for contacting a p-type semiconductor. Alternatively the contact layer 124 in some implementations is formed from materials optimized for contacting a n-type semiconductor. In some implementations, the top contact layer 124 includes an annealed metallization layer. For example, the top contact layer 124 may include a chromium-gold (Cr—Au) layer, a gold-zinc (Au—Zn), a titanium-platinum-gold (TiPtAu) layer, a gold-germanium-nickel (AuGeNi) layer, a palladium-germanium-gold (PdGeAu) layer, or the like. In some implementations, the top contact layer 124 has a thickness in a range from approximately 0.2 μm to approximately 0.8 μm, such as 0.5 μm. In some implementations, the top contact layer 124 has a ring shape, a slotted ring shape, a tooth wheel shape, or another type of circular or non-circular shape (e.g., depending on a design of the VCSEL 100). In some implementations, the top contact layer 124 is a continuation of the metal layer 122 and, therefore, may have a shape that corresponds to or matches the shape of the metal layer 122 (and the shape of the confinement aperture 112).

Second top mirror structure 126 is a top reflector of the optical resonator of the VCSEL 100. In some implementations, the second top mirror structure 126 is configured to increase reflectivity on the side of the VCSEL 100 that includes the first top mirror structure 114 (e.g., the top side of the VCSEL 100). In operation, integration of an optical element, such as a grating or a mode filter, in a BSE VCSEL is less effective (e.g., as compared to top emitting VCSELs) because of high reflectivity and less interaction of cavity modes with the optical element. Reducing a quantity of mirror pairs in a top mirror structure would increase coupling of the cavity modes with such an optical element. However, reducing the quantity of minor pairs in the top minor structure reduces reflectivity in the side of the VCSEL comprising the top minor structure. In VCSEL 100, the second top minor structure 126 serves to increase reflectivity in the side of the VCSEL 100 including the first top mirror structure 114. Therefore, the quantity of minor pairs in the first top minor structure 114 can be reduced so as to increase coupling of cavity modes with the MF structure, and the second top mirror structure 126 can be designed to mitigate the reduction in reflectivity caused by the decrease in the quantity of minor pairs in the first top mirror structure 114. In some implementations, the quantity of mirror pairs in the first top minor structure 114 and the quantity of mirror pairs in the second top minor structure 126 can be optimized so as to provide effective mode filtering with the MF structure while keeping the performance of the VCSEL 100 less sensitive to MF design parameters, which eventually maintains the uniformity of performance of the VCSEL 100.

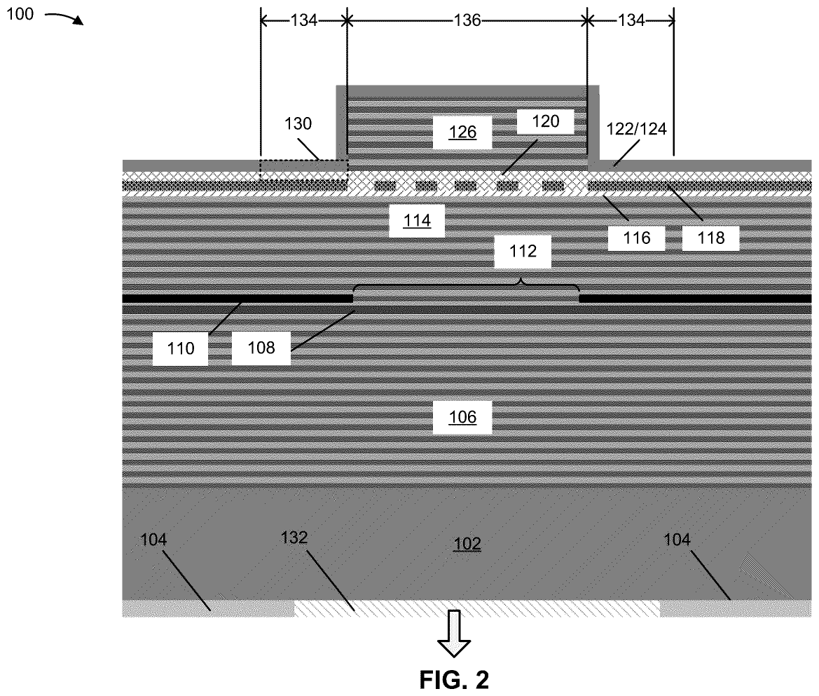

In some implementations, the second top mirror structure 126 may include a plurality of DBR pairs, or another type of mirror structure. In some implementations, the second top mirror structure 126 is formed from a dielectric material. Thus, in some implementations, the second top mirror structure 126 comprises a plurality of dielectric DBR pairs. For example, the second top mirror structure 126 may comprise a plurality of SiO₂/SiNx minor pairs, a plurality of SiO₂/titanium dioxide (TiO₂) minor pairs, or a plurality of Al₂O₃/TiO₂ mirror pairs, among other examples. Alternatively, the second top mirror structure 126 may in some implementations be formed from a p-type material. Thus, in some implementations, the second top mirror structure 126 comprises a plurality of p-type DBR pairs, an example of which is shown in, and described below with respect to, FIG. 2. Alternatively, the second top minor structure 126 may in some implementations be formed from an n-type material. In some implementations, the second top mirror structure 126 may have a thickness in a range from approximately 2.0 μm to approximately 5.0 μm, such as 2.5 μm. In some implementations, a quantity of mirror pairs in the second top minor structure 126 is in a range from three minor pairs to eight mirror pairs.

The top metal 128 is a top metal layer at a front side of the VCSEL 100. In some implementations, the top metal 128 may be a layer that makes electrical contact with the top contact layer 124 (e.g., through vias in the second top mirror structure 126). In some implementations, the top metal 128 may serve as a cathode for the VCSEL 100. In some implementations, the top metal 128 may comprise a plating metal (e.g., a gold (Au)) and/or a seed metal (e.g., TiW/Au).

As noted above, the VCSEL 100 comprises the MF structure that provides mode filtering for light generated in the VCSEL 100. For example, the MF structure may at least partially suppress all HOMs of the VCSEL 100, such that light emitted by the VCSEL 100 is substantially in only the fundamental mode (e.g., such that the VCSEL 100 is a single-mode VCSEL). As another example, the MF structure may be configured to at least partially suppress some HOMs of the VCSEL 100 such that the light emitted by the VCSEL 100 is substantially in a small number of (selected) modes (e.g., such that the VCSEL 100 is a multi-mode VCSEL in which modes are controlled or selected based on the design of the MF structure).

As noted above, the MF structure may comprise the MF layer 130—formed from a portion of the dielectric layer 120 and the (optional) metal layer 122—and the second top mirror structure 126. In some implementations, as shown in FIG. 1, the MF layer 130 is in a first region 134 of the MF structure (e.g., an outer ring region of the MF structure) and is not in a second region 136 of the MF structure (e.g., an inner circular region of the MF structure). As further shown, the second top minor structure 126 may be in at least the second region 136 of the MF structure. For example, as shown in FIG. 1, the second top mirror structure 126 may be present in both the first region 134 of the MF structure and the second region 136 of the MF structure, with the portion of the second top minor structure 126 that is in the first region 134 being over the MF layer 130. In some implementations, a size (e.g., an outer diameter) of the second region 136 of the MF structure differs from a size of the confinement aperture 112 (e.g., an oxide aperture) of the VCSEL 100 by an amount that is less than approximately 2.0 μm. In some implementations, the size of the second region 136 of the MF structure may be larger than the size of the confinement aperture 112. Alternatively, the size of the second region 136 of the MF structure may in some implementations be smaller than the size of the confinement aperture 112. In some implementations, a size (e.g., an outer diameter) of the first region 134 of the MF structure differs from a size of the confinement aperture (e.g., an oxide aperture) of the VCSEL 100 by an amount that is in a range from approximately 4.0 μm to approximately 6.0 μm. In some implementations, a size (e.g., a width) of a ring region defined by the first region 134 and the second region 136 is in a range from approximately 1.5 μm to approximately 3.5 μm.

The MF layer 130 is a layer to at least partially suppress one or more HOMs of light generated in the VCSEL 100. As shown in FIG. 1, the MF layer 130 may in some implementations comprise the metal layer 122 over the portion of the dielectric layer 120 in the first region 134. In some implementations, the dielectric layer 120 may have a thickness t (i.e., a thickness of the dielectric layer 120 in the MF 130) in a range from approximately 0.92×(λ/n_{d}) and approximately 1.45×(λ/n_{d}), where λ is the wavelength of the VCSEL 100 and n_{d} is a refractive index of the dielectric material. More generally, the dielectric layer 120 may have a thickness T that is equal to the thickness t plus or minus a value corresponding to a multiple of the wavelength of the VCSEL 100 divided by two times the refractive index of the dielectric material equal (e.g., T=t±X×λ/(2*n_{d}), where 0.92×(λ/n_{d})≤t≤1.45×(λ/n_{d}) and X is an integer value such as 0, 1, 2, or the like. In some implementations, the thickness T of the dielectric layer 120 may vary by some amount (e.g., ±10 nm, ±15 nm) depending on VCSEL design. Thus, in some implementations, the dielectric layer 120 has a thickness that is within approximately 15 nm of a value equal to a value in a range from approximately 0.92×(λ/n_{d}) and approximately 1.45×(λ/n_{d}) plus or minus a value equal to X×λ/(2*n_{d}), where λ is the wavelength of the VCSEL, n_{d} is a refractive index of a dielectric material, and X is an integer value. In some implementations, the thickness of the MF layer 130 is not equal to a multiple of one-quarter of an emission wavelength of the VCSEL 100 (e.g., so as to provide mode filtering by destructive interference in the first region 134, as described below).

In practice, as illustrated in FIG. 1, the MF layer 130 provides an offset between mirror pairs in a portion of the second top mirror structure 126 in the first region 134 of the MF structure and mirror pairs in a portion of the second top mirror structure 126 in the second region 136 of the MF structure. This offset provided by the MF layer 130 creates an out-of-phase region in the portion of the second top mirror structure 126 in the first region 134 (e.g., an outer ring region) of the VCSEL 100, while maintaining an in-phase region in the portion of the second top mirror structure 126 in the second region 136. Here, the second region 136 is an in-phase region and features of the VCSEL 100 can be designed to maximize reflectivity, while the first region 134 is an out-of-phase region and features of the VCSEL 100 can be designed to minimize reflectivity. In operation, the HOMs are largely confined to a boundary of the VCSEL 100 aperture and, therefore, an amount of overlap of the HOMs with the in-phase region may be negligible, while an amount of overlap of the HOMs with the out-of-phase region may be significant. As a result of the near confinement of the HOMs to the out-of-phase region, loss in the HOMs increases and the HOMs cease to lase. However, the fundamental mode is largely confined nearer to a center of the aperture and, therefore, an amount of overlap of the fundamental mode with the in-phase region may be significant, while an amount of overlap of the fundamental mode with the out-oh-phase region may be negligible. As a result of the near confinement of the fundamental mode to the in-phase region, loss in the fundamental mode is not significant and the fundamental mode is permitted to lase. In this way, the MF layer 130 may provide mode filtering (e.g., through destructive interference) of one or more HOMs in the first region 134 of the VCSEL 100.

Additionally, the metal layer 122 may in some implementations provide absorption of the HOMs in first region 134 of the VCSEL. Here, the lateral overlap of the HOMs in the first region 134 with the metal layer 122 increases absorption of the HOMs by the metal layer 122 and, therefore, increases modal losses. In this way, the metal layer 122 may provide mode filtering through at least partial absorption of one or more HOMs in the first region 134 of the VCSEL 100.

In some implementations, the MF layer 130 may comprise the portion of the dielectric layer 120 only. That is, in some implementations, the metal layer 122 is optional and therefore may not be present in some implementations in VCSEL 100. In such an implementation, a thickness of the dielectric layer 120 in the first region 134 can be selected in order to create the out-of-phase region.

In some implementations, a total thickness from a bottom surface of the bottom minor structure 106 to a top surface of the second top mirror structure 126 may be in a range from, for example, approximately 7 μm to approximately 9 μm, such as approximately 8 μm. In some implementations, a thickness of one or more of the layers of the VCSEL 100 may be selected in order to provide a structure that achieves high reflectivity (e.g., greater than approximately 99% reflectivity). In some implementations, a smaller total thickness may facilitate growth time reduction of the VCSEL 100 or stress reduction within the VCSEL 100.

The number, arrangement, thicknesses, order, symmetry, or the like, of layers shown in FIG. 1 are provided as an example. In practice, the VCSEL 100 may include additional layers, fewer layers, different layers, differently constructed layers, or differently arranged layers than those shown in FIG. 1. For example, the VCSEL 100 may in some implementations not include a grating in the cap layer 118. In some such implementations, rather than the dielectric layer 120 under the metal layer 122, the cap layer 118 can be etched and, in combination with the metal layer 122, may provide the offset that creates the out-of-phase region. As another example, the VCSEL 100 may include one or more isolation implant regions to prevent free carriers from reaching edges of trenches and/or to isolate adjacent VCSELs 100 from one another (e.g., if the trenches do not fully enclose the VCSELs of the VCSEL 100). Additionally, or alternatively, a set of layers (e.g., one or more layers) of the VCSEL 100 may perform one or more functions described as being performed by another set of layers of the VCSEL 100, and any layer may comprise more than one layer.

FIG. 2 is a diagram associated with an alternative example implementation of a VCSEL 100 including an MF structure as described herein. In the example shown in FIG. 2, the second top minor structure 126 comprises mirror pairs of the same type as the minor pairs included in the first top mirror structure 114. For example, the first top minor structure 114 may include a first plurality of p-type DBR minor pairs, and the second top mirror structure 126 may include a second plurality of p-type DBR minor pairs (e.g., rather than a plurality of dielectric DBR mirror pairs, as illustrated in the example VCSEL 100 in FIG. 1). In such an implementation, the bottom mirror structure comprises a plurality of n-type DBR minor pairs. As another example, the first top minor structure 114 may include a first plurality of n-type DBR mirror pairs and the second top minor structure 126 may include a second plurality of n-type DBR mirror pairs, with the bottom mirror structure comprising a plurality of p-type DBR minor pairs.

In some such implementations, as shown in FIG. 2, the second top mirror structure 126 may form a mesa structure on a surface of the VCSEL 100. In some implementations in which the second top mirror structure 126 comprises the same type of mirror pairs as those in the first top minor structure 114, the second top mirror structure 126 may be formed by an epitaxial regrowth process using, for example, an MOCVD technique.

Notably, in the example implementation of the VCSEL 100 shown in FIG. 2, the second top minor structure 126 is not present in the first region 134 of the MF structure. Here, the same concept as shown in FIG. 1 applies—the MF 130 creates an out-of-phase region with respect to the first region 134 of the VCSEL 100, while maintaining an in-phase region in the second region 136.

The number, arrangement, thicknesses, order, symmetry, or the like, of layers shown in FIG. 2 are provided as an example. In practice, the VCSEL 100 may include additional layers, fewer layers, different layers, differently constructed layers, or differently arranged layers than those shown in FIG. 2. For example, the VCSEL 100 may in some implementations not include a grating in the cap layer 118, as described above.

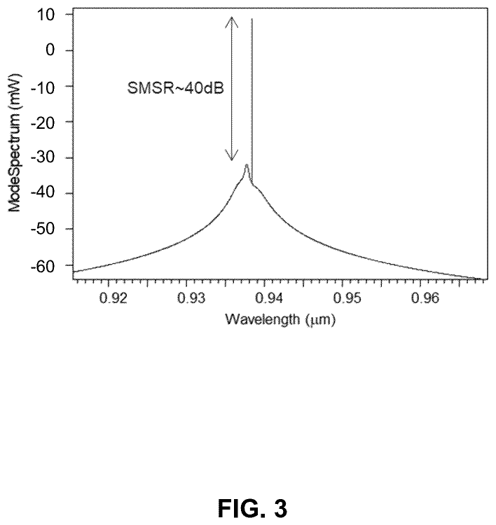

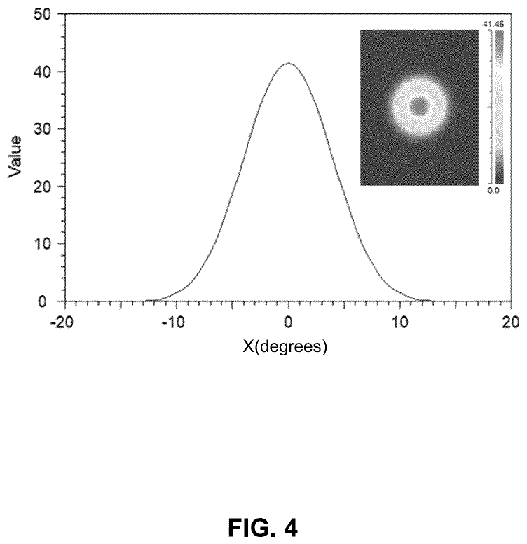

FIGS. 3 and 4 are diagrams illustrating simulation results of a VCSEL 100 including the MF structure described herein. The simulation results are associated with an example VCSEL 100 as illustrated in FIG. 1 including a confinement aperture 112 with a 5.5 μm diameter and second region 136 with a diameter of 6.0 μm, and using a bias current of 8 milliamps (mA). FIG. 3 illustrates an optical spectrum of the VCSEL 100. As shown in FIG. 3, the VCSEL 100 achieves single mode operation with a side mode suppression ratio (SMSR) of approximately 40 decibels (dB). FIG. 4 illustrates a one-dimensional cross-section of a far field of the VCSEL 100, with a two-dimensional view of the far field as an inset. As illustrated in FIG. 4, the far field of the VCSEL 100 resembles a Gaussian-type beam profile.

As indicated above, FIGS. 3 and 4 are provided as examples. Other examples may differ from what is described with regard to FIGS. 3 and 4.

In this way, the VCSEL 100 may provide controllability of operation of the VCSEL 100 with respect to achievement of low divergence, single mode operation (e.g., at high bias currents), or selective multi-mode operation. Thus, the VCSEL 100 may have improved performance uniformity (e.g., as compared to a BSE VCSEL that includes a relatively smaller oxide aperture in association with achieving single mode operation).

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A vertical-cavity surface-emitting laser (VCSEL), comprising:
a first minor structure over a cavity region;
a grating associated with polarizing light emitted by the VCSEL, the grating being over the first minor structure; and
a mode filter (MF) structure over the grating, the MF structure comprising:
an MF layer in a first region of the MF structure to at least partially suppress a higher order transverse mode (HOM) of the light, the MF layer comprising a dielectric layer, and
a second mirror structure in at least a second region of the MF structure to increase reflectivity on a side of the VCSEL comprising the first mirror structure.

2. The VCSEL of claim 1, wherein the first mirror structure comprises a plurality of p-type distributed Bragg reflector (DBR) pairs and the second minor structure comprises a plurality of dielectric DBR pairs.

3. The VCSEL of claim 1, wherein the MF layer comprises a metal layer over the dielectric layer.

4. The VCSEL of claim 3, wherein the metal layer comprises a same material as a contact layer of the VCSEL, a same material as a seed metal of the VCSEL, or a same material as a plating metal of the VCSEL.

5. The VCSEL of claim 1, wherein the MF layer comprises only the dielectric layer.

6. The VCSEL of claim 1, wherein the MF layer provides an offset between the first region of the MF structure and the second region of the MF structure.

7. The VCSEL of claim 1, wherein the first minor structure comprises a first plurality of p-type DBR pairs and the second mirror structure comprises a second plurality of p-type DBR pairs.

8. The VCSEL of claim 1, wherein a size of the second region of the MF structure differs from a size of an oxide aperture of the VCSEL by an amount that is less than approximately 2.0 micrometers (μm).

9. The VCSEL of claim 1, wherein a size of the first region of the MF structure differs from a size of an oxide aperture of the VCSEL by an amount that is in a range from approximately 4.0 micrometers (μm) to approximately 6.0 μm.

10. The VCSEL of claim 1, wherein a size of a ring region defined by the first region and the second region is in a range from approximately 1.5 micrometers (μm) to approximately 3.5 μm.

11. The VCSEL of claim 1, wherein a quantity of mirror pairs in the second mirror structure is in a range from three minor pairs to eight mirror pairs.

12. The VCSEL of claim 1, wherein a quantity of mirror pairs in the first minor structure is in a range from seven mirror pairs to seventeen mirror pairs.

13. The VCSEL of claim 1, wherein the VCSEL is a backside emitting (BSE) VCSEL.

14. The VCSEL of claim 1, wherein a thickness of the dielectric layer is selected so as to cause destructive interference in reflectivity in the first region of the MF structure.

15. The VCSEL of claim 1, wherein a thickness of the MF layer is not a multiple of one-quarter of an emission wavelength of the VCSEL.

16. The VCSEL of claim 1, wherein the dielectric layer in the MF layer has a thickness that is within 15 nanometers of a value equal to a value in a range from approximately 0.92×(λ/n_{d}) and approximately 1.45×(λ/n_{d}) plus or minus a value equal to X×λ/(2*n_{d}), where λ is the wavelength of the VCSEL, n_{d} is a refractive index of a dielectric material, and X is an integer value.

17. A backside emitting (BSE) vertical-cavity surface-emitting laser (VCSEL), comprising:
a first mirror structure over a cavity region; and
a mode filter (MF) structure over the first mirror structure, the MF structure comprising:
an MF layer in a first region, the MF layer being associated with suppressing one or more modes of light emitted by the BSE VCSEL,
wherein the MF layer comprises at least a dielectric layer, and
a second mirror structure in at least a second region, the second mirror structure being associated with increasing reflectivity on a side of the BSE VCSEL that includes the first mirror structure.

18. The BSE VCSEL of claim 17, further comprising a grating over the first mirror structure, the grating being associated with polarizing the light emitted by the BSE VCSEL.

19. The BSE VCSEL of claim 17, wherein the MF layer further comprises a metal layer over the dielectric layer in the first region.

20. A vertical-cavity surface-emitting laser (VCSEL), comprising:
a mode filter (MF) structure comprising:
an MF layer to provide an offset between a first region of the MF structure and a second region of the MF structure in association with at least partially suppressing one or more modes of light emitted by the VCSEL by causing destructive interference in reflectivity in the first region of the MF structure; and
a mirror structure in at least the second region to increase reflectivity on an epitaxial side of the VCSEL.
